(19) United States
(12) Patent Application Publication
(10) Pub. No.: US 2011/0174525 A1
(43) Pub. Date: Jul. 21, 2011

(54) Method and Electronic Assembly to Attach a Component to a Substrate

(75) Inventors: Timothy R. Conrad, Kokomo, IN (US); Theresa Ann Updike Thompson, Kokomo, IN (US); Terry L. Warner, Sharpsville, IN (US); Daniel E. Kettles, Russiaville, IN (US); Phuc B. Dao, Westfield, IN (US)

(73) Assignee: DELPHI TECHNOLOGIES, INC., Troy, MI (US)

(21) Appl. No.: 12/690,297

(22) Filed: Jan. 20, 2010

(51) Int. Cl. H05K 1/18; B23K 31/02; H05K 1/09

(52) U.S. Cl. 174/257; 228/256; 174/260

(57) ABSTRACT

A method and an electronic assembly for attaching a component to a substrate, or printed circuit board, is recited. The printed circuit board comprises a solder-nonwettable surface and a bond pad being formed of a solder-wettable surface. The printed circuit board defines a through hole extending through the printed circuit board and the bond pad. A plate lining a first portion of the through hole in the printed circuit board is formed of a solder-wettable material. Solder paste is applied to the bond pad and into the through hole. A component including a terminal overlies the bond pad in an arrangement. Reflowing the solder paste forms a solder fillet that bonds the terminal to the bond pad. The solder fillet extends within the through hole attaching the component to the printed circuit board.

### TECHNICAL FIELD

This invention relates to a method to attach a component to a substrate, more particularly, this invention relates to providing a substrate, or printed circuit board, with a through hole extending through a bond pad and into the printed circuit board, and a plate lines the through hole in the printed circuit board, applying a solder paste overlying the bond pad and into the through hole, arranging a component overlying the bond pad on the solder paste, and reflowing the solder paste forming solder that is drawn onto the bond pad, and creating a solder fillet extending within the through hole that bonds the terminal to the bond pad, and bonds the component to the printed circuit board.

### BACKGROUND OF INVENTION

It is known to bond a terminal of a component to a bond pad comprising a single uniform area. The bond pad is located on a surface of a substrate, such as a printed circuit board. The component is in contact with solder paste disposed on the bond pad. In an application utilizing surface mount technology, a plurality of terminals of an electronic component that is not a traditional surface mount component, is arranged overlying and level with the bond pad. It is suitable for a capacitor to include additional terminals in addition to the terminal used for the electrical connection, bonded to the same bond pad. The additional terminals are used for mechanical support of the capacitor. Reflow of the solder paste coalesces into solder, forming a single molten melt layer wetting the bond pad and the terminals that solidifies upon cooling. The resulting solder fillet bonds the terminals to the bond pad. The mechanical bonding strength of the solder fillet is limited to the bonding strength of the bond pad attached to the surface of the printed circuit board.

Undesired bonding characteristics are possible when bonding multiple terminals of a component to a bonding pad with a single uniform area. Congregation or pooling of solder below the terminals on the bond pad during reflow of the solder paste lifts the terminals off the bond pad resulting in a raised terminal condition. A raised terminal condition produces an incomplete solder fillet. An incomplete solder fillet is a structurally weak solder fillet having low mechanical and electrical integrity. A solder fillet with low mechanical and electrical integrity compromises effective electrical conductivity and/or mechanical functionality of the capacitor. Additionally, an absence of material, or a void condition, occurring on the solder fillet across the bonding pad as the solder cools, creates a nonuniform, incomplete solder fillet.

Therefore, what is needed is a new method and electronic assembly for bonding a terminal of a component to a bond pad creating a robust, uniform solder fillet having increased mechanical and electrical integrity, while reducing the problematic pooling of solder, raised terminal, and void anomalies, resulting in incomplete, weak solder fillets.

### SUMMARY OF THE INVENTION

In accordance with the preferred embodiment of the invention, a method is provided for attaching a component to a substrate. The method includes providing a printed circuit board comprising the substrate formed of a solder-nonwettable surface and a bond pad disposed on the surface. The bond pad is formed of a solder-wettable material. The printed circuit board defines a through hole extending through the substrate and the bond pad. The through hole comprises a first portion through the substrate and a second portion through the bond pad registering with the first portion. The printed circuit board further includes a plate lining the first portion in the substrate. The plate lining is formed of a solder-wettable material. The method further includes applying a solder paste overlying the bond pad. As the solder paste is applied to the bond pad, the solder paste fills the through hole including the first portion and second portion lined by the plate. The method further includes arranging the component onto the printed circuit board. The terminal of the component is in contact with the solder paste overlying the bond pad forming an arrangement. The method yet further includes reflowing the solder paste to form a solder fillet bonding the terminal to the bond pad. The solder fillet extends into the through hole attaching the component to the printed circuit board.

In accordance with an additional embodiment of the invention, an electronic assembly comprises a printed circuit board, a component, and a solder fillet. The printed circuit board comprises a substrate being formed of a solder-nonwettable surface. A bond pad is disposed on the surface of the substrate. The bond pad is formed of a solder-wettable material. The printed circuit board defines a through hole extending through the substrate and the bond pad. The printed circuit board further includes a plate lining the through hole within the substrate. The plate is formed of a solder-wettable material. A component includes a terminal that overlies the substrate. The terminal is formed of a solder-wettable material and overlies the bond pad. A solder fillet bonds the bond pad to the terminal, and the solder fillet extends into the through hole.

### BRIEF DESCRIPTION OF THE DRAWINGS

This invention will be further described with reference to the accompanying drawings in which:

FIG. 1 is a top view of an electronic assembly in accordance with the present invention;

FIG. 2 is a cross section view of the electronic assembly in FIG. 1, taken along the line 2-2 in the direction of the arrows;

FIG. 3 is a top view of the electronic assembly of FIG. 1 with the component removed, showing details thereof;

FIG. 4 is a cross section view along the printed circuit board of the electronic assembly of FIG. 3, taken along the line of 4-4 in the direction of the arrows; and

FIG. 4A is a magnified view along the printed circuit board of the electronic assembly of FIG. 4, showing the details thereof.

### DETAILED DESCRIPTION OF THE PREFERRED EMBODIMENT

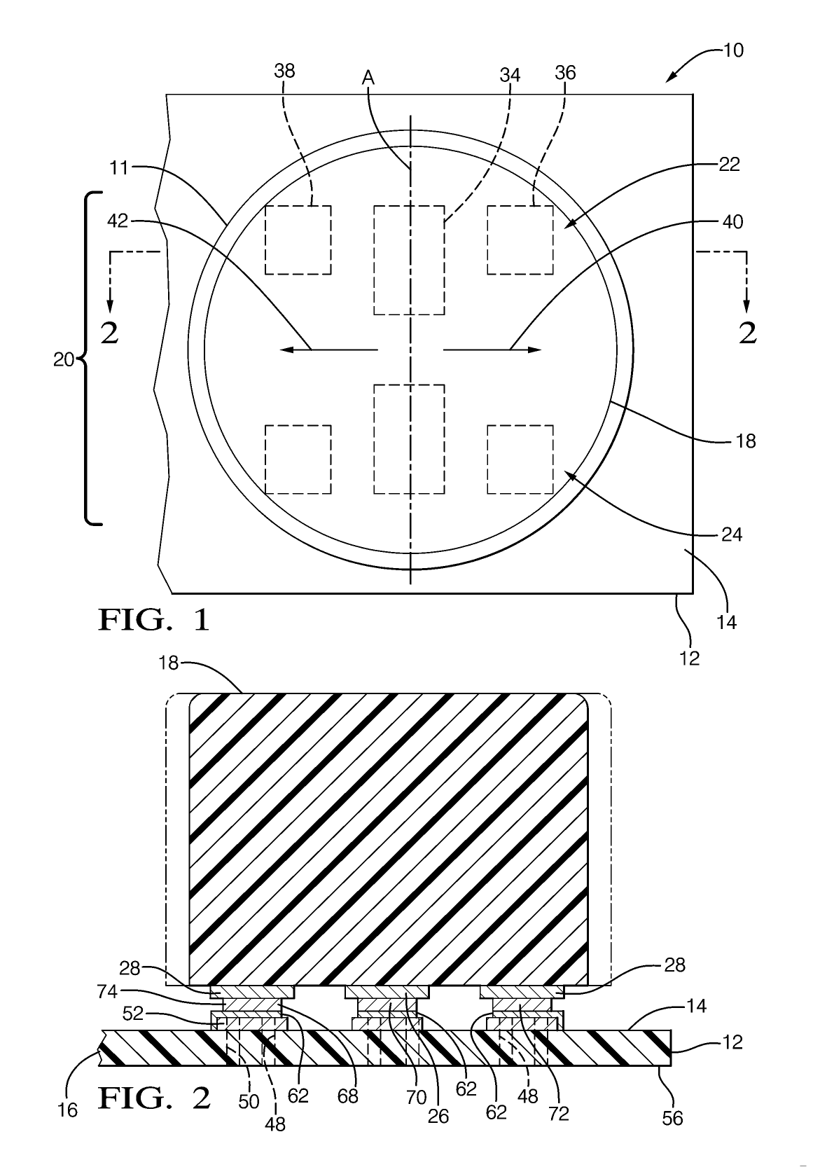

In accordance with the present invention, referring to FIGS. 1-2, an electronic assembly 10, comprises a component 11 arranged overlying a substrate 12 with additional surface mount components or devices (not shown). Substrate 12 is formed of a solder-nonwettable material comprising ceramic, FR4 printed circuit board, or the like. Substrate 12 comprises a first substrate surface 14. Surface mount devices are placed on surface 14 of a printed circuit board 16 using surface mount technology manufacturing processes. Component 11 is a capacitor 18, however, capacitor 18 is not a typical surface mount device. Capacitor 18 is a component assembly (not shown) being formed and placed on surface 14 of printed circuit board 16 in a manner similar to typical surface mount devices utilizing surface mount technology manufacturing processes.

Printed circuit board 16 comprises bond pads 20 disposed on surface 14 for bonding capacitor 18. Pad 20 comprises a solder-wettable material formed of an electrically conductive metal such as brass, copper, tin, nickel, silver, or gold, or the like. Pad 20 comprises a positive terminal bond pad 22 and a negative terminal bond pad 24.

Referring to FIGS. 1 and 2, capacitor 18 is arranged overlying pad 20. Capacitor 18 comprises positive terminal 26 and first support terminals 28 in proximity to positive terminal 26. First support terminals 28 serve to mechanically support capacitor 18. Positive terminal 26 and first support terminals 28 overlie positive terminal bond pad 22. Terminals 26, 28 are formed of a solder-wettable material similar to pad 20 recited herein. Positive terminal 26 and first support terminals 28 bond to positive terminal bond pad 22.

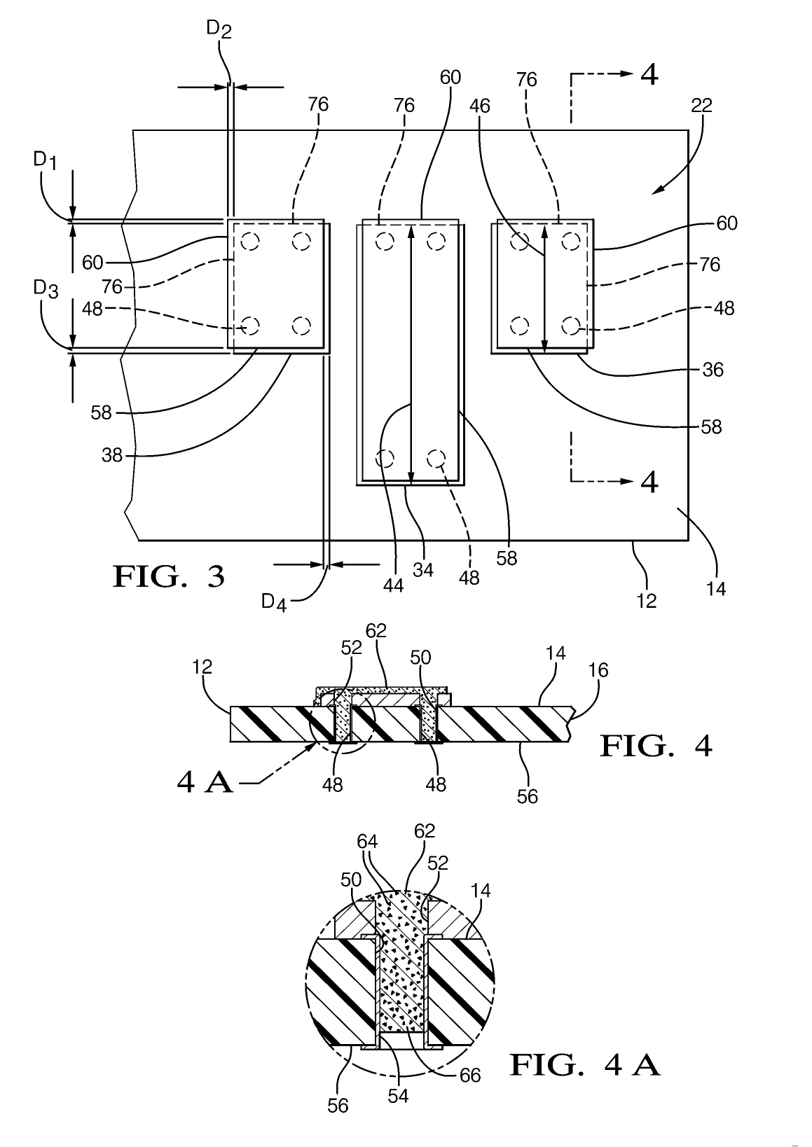

Referring to FIG. 3, positive terminal bond pad 22 comprises a first section 34, a second section 36, and a third section 38. Second section 36 is laterally spaced apart from first section 34 in a first direction 40 and third section 38 is laterally spaced apart from first section 34 in a second direction 42 opposite first direction 40. First section 34 has a longitudinal axis A parallel to surface 14 with first section 34 having a first axial length 44 and second section 36 having second axial length 46 less than first axial length 44. First section 34 of pad 22 is in electronic communication with positive terminal 26 of capacitor 18. Second section 36 and third section 38 of pad 22 are used to bond first support terminals 28 of capacitor 18 with printed circuit board 16.

Referring to FIGS. 4-4A, each section 34, 36, 38 comprises through holes 48. Printed circuit board 16 defines a first portion 50 of a through hole 48 extending through substrate 12 in first section 34. A second portion 52 of through hole 48 extends through first section 34 of pad 22 and registers with first portion 50. First portion 50 and second portion 52 are perpendicular to surface 14. Through hole 48 further comprises a plate 54 lining first portion 50 of printed circuit board 16. Plate 54 is formed of the solder-wettable material. Plate 54 is in electrical connection with first section 34 of positive terminal bond pad 22. Additionally, plate 54 is formed of an electrically conductive metal such as brass, copper, tin, nickel, silver, or gold, or the like, similar to bond pad 20.

Referring to FIG. 3, each section 34, 36, 38 of bond pad 22 comprises a plurality of through holes 48. Sections 34, 36, 38 of bond pad 22 have a rectangular shape, with through holes 48 disposed on sections 34, 36, 38 of positive terminal bond pad 22. Through holes 48 are located in the proximity of the inside corners of each section 34, 36, 38. Each section 34, 36, 38 comprises four distinct through holes 48.

Positive terminal 26 of capacitor 18 on first section 34 of bond pad 22 is in electrical communication through a conductive pathway, or trace (not shown), within an electronic circuit (not shown) disposed on printed circuit board 16. Preferably, electrical connection of positive terminal 26 of capacitor 18 is made to first section 34 on positive terminal bond pad 22 on surface 14 of printed circuit board 16. Alternately, conductive trace (not shown) is readily adapted to electrically connect first section 34 by through hole 48 on plate 54 on a second substrate surface 56 opposite surface 14.

Referring to FIG. 3, each section 34, 36, 38 has a part 58 overlying each section 34, 36, 38 and onto a region of substrate surface adjacent each section 60. Part 58 is distinct and noncontiguous for each section 34, 36, 38. A solder paste 62 is applied to part 58 overlying each section 34, 36, 38 and onto a region of substrate surface adjacent each section 60. Referring to FIG. 4A, solder paste 62 comprises solder particles 64 dispersed in a flux, or vaporizable vehicle 66. Solder particles 64 are typically formed of metallic elements such as tin and lead. Reflowing solder paste 62 results in the formation of a solder fillet 68 that is distinct for each section 34, 36, 38. Solder fillet 68 extends into through hole 48.

Capacitor 18 further comprises a negative terminal (not shown) and second support terminals (not shown) in proximity to the negative terminal (not shown). Negative terminal (not shown), second support terminals (not shown), and negative terminal bond pad 24 have structure and through holes 48 similar to positive terminal 26, first support terminals 28, and positive terminal bond pad 22, recited herein. Referring to FIG. 1, negative terminal (not shown) and second support terminals (not shown) overlie negative terminal bond pad 24 and bond to negative terminal bond pad 24 in a similar manner as positive terminal 26 and first support terminals 28 to positive terminal bond pad 22, recited herein.

A method for attaching component 11 to substrate 12, referring to FIGS. 1-4A, comprises providing printed circuit board 16 including surface 14 with pad 20 on surface 14, and through holes 48 on positive terminal bonding pad 22. The method further comprises applying solder paste 62 to part 58 on each section 34, 36, 38 and filling second portion 52 and first portion 50 of through holes 48, and onto region of the substrate surface adjacent each sections 60 of pad 22. The method additionally comprises arranging capacitor 18 onto printed circuit board 16 to form an arrangement overlying bond pads 22, 24. Capacitor 18 is arranged such that positive terminal 26 overlies first section 34 in contact with part 58 of first section 34, and first support terminals 28 overlie sections 36, 38 in contact with part 58 on second section 36 and part 58 on third section 38. Solder paste 62 on part 58 is used to temporarily hold capacitor 18 to pads 22, 24 before reflow.

The method yet further comprises reflowing solder paste 62 forming a solder fillet 68 without overheating and damaging capacitor 18. Solder fillet 68 comprises a first solder fillet 70, a second solder fillet 72, and a third solder fillet 74. First solder fillet 70 bonds first section 34 to positive terminal 26. Second and third solder fillets 72, 74 bond first support terminals 28 to second section 36 and third section 38. Each solder fillet 70, 72, 74 is distinct from each other solder fillet. Reflowing solder paste 62 includes heating assembly 10 including solder paste 62 for a time and at a temperature effective to vaporize vaporizable vehicle 66, whereupon the solder coalesces and melts forming a singular molten melt layer (not shown) that is drawn or wicked into sections 34, 36, 38 from regions of substrate surface adjacent each section 60. Regions of substrate surface adjacent each section 60 are sized effectively to draw the singular molten melt layer (not shown) into sections 34, 36, 38 and into through holes 48. The singular molten melt layer (not shown) wets sections 34, 36, 38, terminals 26, 28, and through holes 48 in sections 34, 36, 38, and is cooled solidifying the solder to form distinct solder fillets 70, 72, 74 overlying sections 34, 36, 38. Solder fillets 70, 72, 74 extend into through holes 48 in sections 34, 36, 38.

Solder drawn into through holes 48 in sections 34, 36, 38 and subsequently cooled provides additional mechanical mounting strength for fillets 70, 72, 74 and increase electrical conductivity for capacitor 18. Solder fillets 70, 72, 74 robustly bond terminals 26, 28 to bond pad 22, thus, attaching capacitor 18 to printed circuit board 16. A solder fillet with a smooth surface (not shown) having a high reflectivity of light typically coincides with a solder joint having high mechanical integrity and high electrical conductivity.

Providing a separate section of bonding pad for each terminal that includes through holes increases the mechanical and electrical integrity of the solder fillet. Negative terminal (not shown) of capacitor 18 and second support terminals (not shown) are arranged over negative terminal bond pad 24 and reflowed in similar fashion to positive terminal 26 on positive terminal bond pad 22, as recited herein.

Part 58 overlying each section 34, 36, 38 and onto region of substrate surface adjacent each section 60 needs to be effectively sized to provide the volume of solder necessary along with drawing solder effectively into each section 34, 36, 38 and through hole 48 to produce robust solder fillets. Not providing the overprinting of part 58 onto region of substrate surface adjacent each section 60 results in an undesired weak, incomplete solder fillet. Referring to FIG. 3, regions of substrate surface adjacent each section 60, preferably, have a distance D₁ or D₂ exceeding an edge 76 of each section 34, 36, 38 by less than or equal to about 1.0 millimeter. More preferably, regions of substrate surface adjacent each section 60 have distance D₁ or D₂ exceeding edge 76 by less than or equal to about less than or equal to about 0.4 millimeter. Preferably, the a distance D₃ and D₄ between part 58 and each section 34, 36, 38 for solder paste 62 overlying the section within each section 34, 36, 38 is less than or equal to about 0.1 millimeter.

In an alternate embodiment, component 11 is suitable to be an inductor, or a mechanical post. A mechanical post (not shown) is readily adapted to provide mechanical support to a structure disposed on printed circuit board 16.

In a further alternate embodiment, through hole location on the section of the bond pad is suitable to be at any location within an area of each section of the bond pad. The number of through holes utilized in a section is dependent on the mechanical support requirements needed for a specific component.

In yet a further alternate embodiment, the printed circuit board comprises more than one printed circuit board layer, and the through hole extends through the more than one printed circuit board layer. The component is readily adapted to be electrically connected to the electronic circuit by connection with the bond pad or the plate at any printed circuit board layer.

Thus, this invention provides a method and an assembly for robustly attaching an component to a bond pad on a substrate creating uniform solder fillets that have increased mechanical integrity and electrical conductivity on the printed circuit board. The regions of the substrate surface adjacent each section of the bond pad on the printed circuit board allow solder to be drawn into each sections and into the through holes, creating distinct, uniform solder fillets while anchoring the component to the printed circuit board as opposed to only along the surface of the printed circuit board. The solder in the through holes are an extension of the solder fillet on the bond pad providing additional mechanical strength to the solder fillet and the component. Further, plate on the through holes in the substrate is in electrical communication with the bond pad, and the bond pad and the plate are formed of an electrically conductive metal. The electrical conductivity of the bond pad and the plate provides flexibility regarding the connection of the component within an electronic circuit on the printed circuit board. The connection of the component to the electronic circuit by conductive traces is suitable to be realized on the substrate surface to the bond pad, or to the plate on the through hole on the second substrate surface opposite the first surface. A plurality of through holes is readily adapted to be disposed on the bond pad for additional mounting strength of the component to the printed circuit board. The through holes on the bond pad are suitable to be effectively used on printed circuit boards having more than one printed circuit board layer. The invention is easily integrated into existing surface mount technology manufacturing processes avoiding the need and the increased expense for additional manufacturing processes to place components to produce solder fillets comprising increased electrical and mechanical integrity.

While this invention has been described in terms of the preferred embodiment thereof, it is not intended to be so limited, but rather only to the extent set forth in the claims that follow.

We claim:

1. A method for attaching a component to a substrate, said method comprising:
providing a printed circuit board comprising the substrate formed of a solder-nonwettable surface and a bond pad disposed on said surface and formed of a solder-wettable material, said printed circuit board defining a through hole extending through the substrate and the bond pad, said through hole comprising a first portion through the substrate and a second portion through the bond pad registering with a first portion, said printed circuit board further including a plate lining the first portion in the substrate, said plate lining formed of a solder-wettable material;
applying a solder paste to the bond pad such that the solder paste fills the through hole including the second portion through the bond pad and the first portion through the substrate lined by the plate;
arranging the component onto the printed circuit board such that a terminal of the component is in contact with the solder paste overlying the bond pad on the substrate, thereby forming an arrangement; and
reflowing the solder paste to form a solder fillet bonding the terminal to the bond pad and extending within the through hole, to thereby attach the component to the printed circuit board.

2. The method according to claim 1, wherein the step of applying the solder paste includes applying the solder paste into a region of the substrate surface adjacent the bond pad, and wherein the step of reflowing the solder paste includes drawing solder from the adjacent region onto the bond pad.

3. The method in accordance with claim 1, wherein the plate is in electrical connection with the bond pad, and the plate and the bond pad are formed of an electrically conductive metal.

4. The method in accordance with claim 3, wherein the component is in electric communication with an electronic circuit disposed on the printed circuit board, said printed circuit board further comprises conductive traces connecting the plate or the bond pad of the component with the electronic circuit.

5. The method in accordance with claim 3, wherein said electrically conductive metal comprises brass, copper, nickel, tin, silver, or gold.

6. The method in accordance with claim 1, wherein the bond pad comprises a plurality of through holes.

7. The method in accordance with claim 6, wherein the bond pad has a rectangular shape further defining inside corners, and the through hole is in proximity to each inside corner within the bond pad.

8. The method in accordance with claim 1, wherein the solder paste comprises solder particles dispersed in a vaporizable vehicle.

9. The method in accordance with claim 1, wherein the printed circuit board comprises more than one printed circuit board layer, and the through hole extends through the more than one printed circuit board layer.

10. An electronic assembly, comprising:
a printed circuit board comprising a substrate formed of a solder-nonwettable surface and a bond pad disposed on said surface and formed of a solder-wettable material, said printed circuit board defining a through hole extending through the substrate and the bond pad, the printed circuit board further including a plate lining the through hole within the substrate and formed of a solder-wettable material;
a component overlying the substrate, said component having a terminal formed of solder-wettable material and overlying the bond pad; and
a solder fillet bonding the bond pad to the terminal, said solder fillet extending within the through hole.

11. The electronic assembly in accordance with claim 10, wherein the plate is in electrical connection with the bond pad, and the plate and the bond pad are formed of an electrically conductive metal.

12. The electronic assembly in accordance with claim 11, wherein the component is in electric communication with an electronic circuit disposed on the printed circuit board, said printed circuit board further comprises conductive traces connecting the plate or the bond pad of the component with the electronic circuit.

13. The electronic assembly in accordance with claim 11, wherein said electrically conductive metal comprises brass, copper, nickel, tin, silver, or gold.

14. The electronic assembly in accordance with claim 10, wherein the bond pad comprises a plurality of through holes.

15. The electronic assembly in accordance with claim 14, wherein the bond pad has a rectangular shape further defining inside corners, and the through hole is in proximity to each inside corner within the bond pad.

16. The electronic assembly in accordance with claim 10, wherein the printed circuit board comprises more than one printed circuit board layer, and the through hole extends through the more than one printed circuit board layer.
